(19) United States
(12) Patent Application Publication
(10) Pub. No.: US 2022/0212813 A1
(43) Pub. Date: Jul. 7, 2022

(54) Urban Drone Corridor

(71) Applicant: Ming Zhang, Montreal (CA)

(72) Inventor: Ming Zhang, Montreal (CA)

(21) Appl. No.: 17/140,903

(22) Filed: Jan. 4, 2021

(51) Int. Cl. B64F 1/36; B64C 39/02; B64D 47/04; B60L 53/80; E04B 1/92; E04B 1/82; E04H 6/44; H05K 9/00; G05D 11/13

(52) U.S. Cl. CPC B64F 1/362; B64C 39/024; B64D 47/04; B60L 53/80; E04B 1/92; E04B 1/8218; E04B 2001/925; H05K 9/0003; G05D 11/137; B64C 2201/027; B64C 2201/128; B60L 2200/10; E04H 6/44

(57) ABSTRACT

An unmanned aerial vehicle (UAV) passage with physically real housing and enclosure, provides a reliable and secure aerial path space for the UAV in the populated urban areas. The ability of the modern UAV system to make an exact movement, as well as the high precision achieved by the indoor position system, makes regular UAV travel in a physically real tunnel-like corridor unchallenging. Appropriately lightened, EMI shielded, pressurized, with a wired and wireless communication link, the UAV passage creates a safe, reliable, and regulation-compliant flying environment for autonomous UAV flight missions or UAV deliveries deep in the urban areas surrounded by high rise buildings or clouded by controlled/restricted airspaces.

### FIELD OF THE INVENTION

The present invention relates generally to the field of constructing a safe, reliable, and efficient aerial transportation infrastructure for unmanned aerial vehicles (UAV), commonly referred to as drones.

### BACKGROUND OF THE INVENTION

Many time-critical first-mile and last-mile logistics originate and end in the urban areas, calling for the application of unmanned aerial vehicles (UAV). Despite many advantages foreseen, regular UAV flights or delivery services have not been achieved in the urban areas that are clouded by restricted or controlled airspaces.

Even in the urban areas where the regulation allows the use of the UAV, the UAV faces challenges such as unpredictable near-ground wind, attenuated weak GNSS signal, deliberated drone jamming, unexpected EMI interference, bad weather conditions, as well as public concerns about noise, privacy, and safety associated with the UAV.

Prior art reference U.S. Pat. No. 10,351,239, “Unmanned aerial vehicle delivery system”, discloses a UAV delivery system capable of virtual route planning in the sky. In the multi-corridor sections of the suggested virtual route, if two UAVs fly side by side, one UAV can take advantage of the wind created by another UAV. When two UAVs fly too close to each other, the avoidance system on the UAVs will ensure that a collision does not occur. It suggests enclosures be built individually in the first or second zone for security reasons. It does not discuss any UAV passage with enclosure connecting the two zones.

Prior art reference U.S. Pat. No. 10,580,310, “UAV routing in utility rights of way”, disclose a method using power line right of way as virtual tunnel-like UAV routing. It does not discuss any UAV passage physically built.

Prior art reference U.S. Pat. No. 10,835,070, “Safe mail delivery by unmanned autonomous vehicles”, disclose a method and a system for delivering mails by UAV into a specially designed mail receptacle. It discusses enforcing a virtual track path with Inverse-Geofencing, but it does not discuss any UAV passage physically built.

The global navigation satellite system (GNSS), including the global positioning system (GPS), becomes unreliable in interior spaces because there is no visual contact with the satellites. A large variety of indoor positioning systems (IPS) based on lights, radio waves, magnetic fields, acoustic signals have been developed and deployed in an indoor environment where GNSS or GPS lose their signal strength or experience a lack of accuracy.

Electromagnetic interference (EMI) can be found in many places, and can adversely affect the UAV operation. Furthermore, drone jammers are being developed against UAV. They will jam the frequency that a UAV uses to communicate with its ground station, forces the drone to activate its return to home function. Shielded enclosures, referred to as Faraday cages or metal structures connected to the ground are capable of preventing external radiofrequency energy from entering into the enclosure and preventing the strong internal signal from leaking out.

The performance of widely used multi-rotor drones, for example, the quadcopters, depends on air density that varies at different altitudes. The greater the density of the air, the greater the rotor efficiency, engine power output, and aerodynamic lift. Fixed-wing types of drones, being able to fly due to the lift force acting on the fixed wings, benefit also from dense air since the amount of lift produced is proportional to the density of the air. Air density changes with pressure, temperature, and humidity. In general, the greater the altitude, the less dense the air becomes, the less atmospheric pressure a given volume of air has.

Modern drones, especially the multi-copter type such as quadcopters are easy to fly in any direction and hover in place smoothly. Their propeller's direction along with the drone's motor rotation and speed, make such a level of maneuverability possible. Beyond the basic command-and-control flow as following: Remote Control Stick Movement/Central Flight Controller/Electronic Speed Control Circuits/Motors and Propellers/Quadcopter Movement or Hover, the flight controllers also make additional computation using programmed flight parameters and algorithms based on inputs from the encompassed inertial measurement unit, GPS, Gyroscope and other sensors, to achieve the high stability and maneuverability. Nowadays, the UAV system is capable of making exact movement necessary within centimeters of a structure.

Nevertheless, wind remains one of the biggest concerns in UAV flight missions and a major determinant of whether or not a UAV is capable of carrying out its mission.

Although manned aircraft accidents due to strong wind are rare nowadays, the low altitude flying UAVs, with their smaller size, lighter weight, lower speed are involved in many accidents and are more susceptible to wind disturbance than manned aircraft. Among all the wind effects such as constant wind, turbulent flow, wind shear, and propeller vortex, wind shear is the most dangerous wind field which can make the UAV out of control temporarily. When the UAVs fly in close formation one after another, the propeller vortices of the leading UAV can affect the following UAV. Fortunately, the speed of the UAV is generally low, so the following UAV could stabilize itself and avoid dropping off, however at a cost of wasting limited battery power.

Wind shear, sometimes called wind gradient, is a significant difference in speed and/or direction at a short distance. A wind gust, however, is an increase in wind speed at the surface, generally in the same direction as the prevailing wind.

### SUMMARY OF THE INVENTION

The purpose of the present invention is to provide a physically real passage with closed housing for aerial transportation using an unmanned aerial vehicle (UAV). The UAV passage is equipped with wired and wireless communication links, accurate network-based indoor positioning, appropriate lighting, EMI shielding, air density regulation, anemometers, and other climate weather sensors. The UAV passage of the present invention is further divided into multiple corridors superposed vertically, enabling simultaneous UAV flights at different altitudes, reducing the construction cost of the passage associated with acquiring the right of way in the urban area. With additional lining, the UAV passage is configured to provide preferentially airflow resistance, noise dampening, impact attenuation, or thermal insulation. Such a UAV passage creates a safe, efficient, almost foolproof flying route for a UAV in autonomous waypoint flight mode, improving the safety of UAV travels, boosting the performances of the UAV, and making the regular UAV flight mission and UAV delivery possible in urban areas and under all weather conditions.

### BRIEF DESCRIPTION OF THE DRAWINGS

Other uses and advantages of the present invention will become apparent to those skilled in the art upon reference to the specification and the drawings, in which:

FIG. 1 is a schematic partial cutaway view of the UAV passage with corridors, according to an embodiment of the present invention;

FIG. 1A is a partial cutaway side view of the UAV passage with corridors, having one side of the housing/enclosures partially removed, showing the internal arrangement of the passage.

FIG. 1B is a partial closeup view of the cross-section of the corridor shown in FIG. 1A. Also included are schematic views of airflows, represented by arrow icons, originated from a moving UAV and their interaction with the corrugated lining next to the enclosure;

FIG. 1C is a cross-sectional view of the corridor 12C shown in FIG. 1A.

FIG. 2B is a partial closeup view of the cross-section of a corridor according to an alternative embodiment of the present invention. Also included are schematic views of airflows, represented by arrow icons, originated from a moving UAV and their interaction with the corrugated lining next to the enclosure.

### DESCRIPTION OF THE PREFERRED EMBODIMENTS

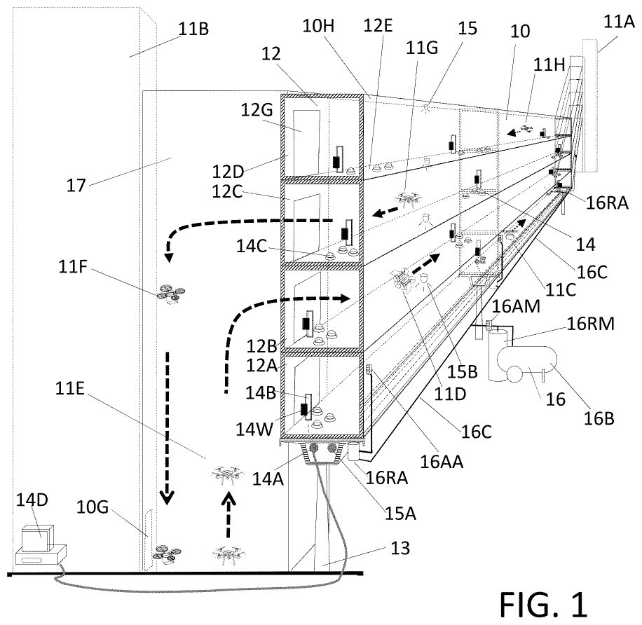

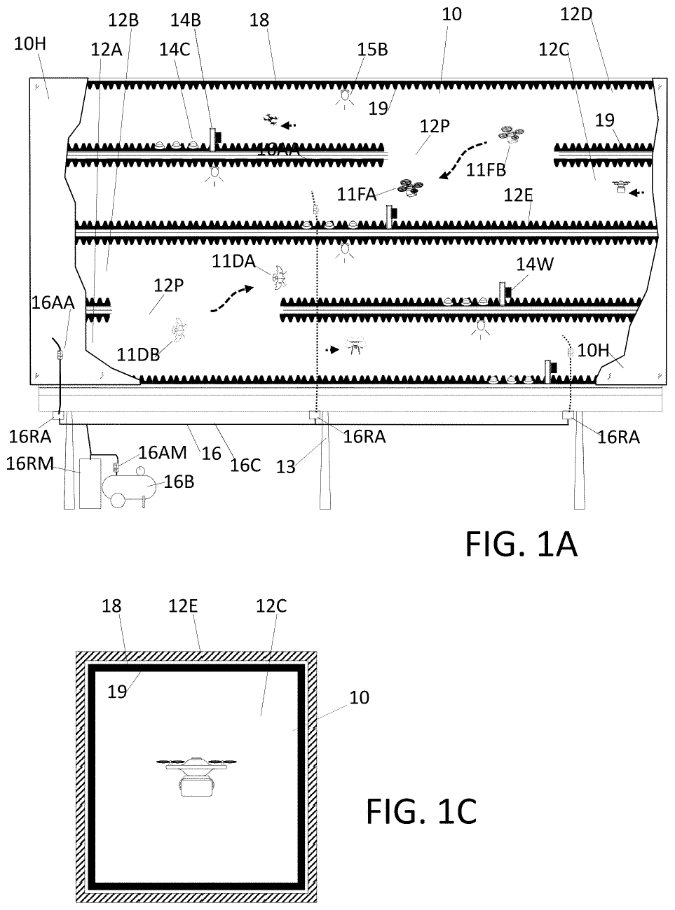

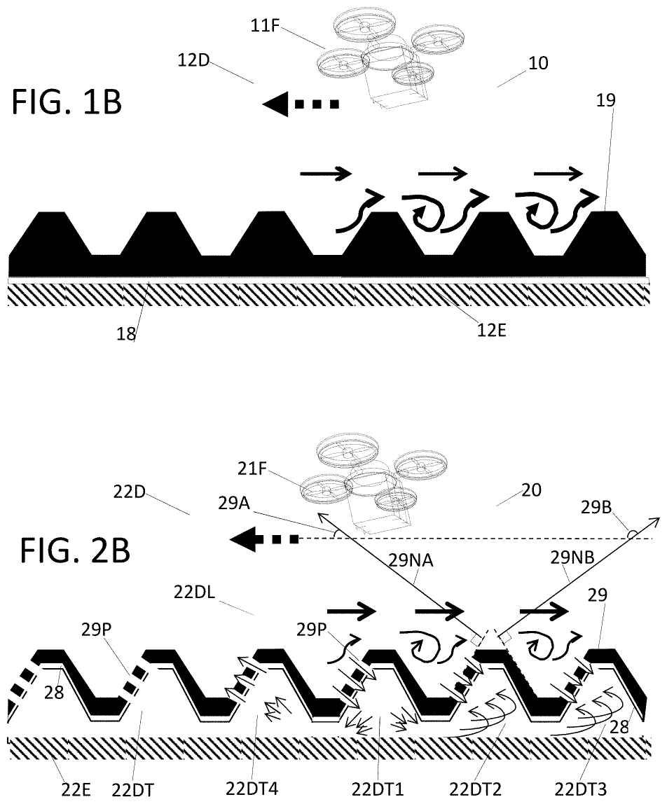

FIG. 1 depicts one embodiment of the present invention, a multi-corridor section 12 of an unmanned aerial vehicle (UAV) passage 10 connecting two UAV terminals 11A and 11B, wherein a plurality of UAV 11C, 11D, 11E, 11F, 11G, and 11H are traveling.

The UAV passage 10 is physically constructed with a housing 10H at the exterior to protect the interior, a path space confined by the housing 10H, from undesirable weather conditions such as strong wind, heavy rain, or snow. The UAV passage 10 has at least one gate 10G at each end in connection with the terminal 11A and 11B. The gate 10G is generally kept closed and only opens when the UAV enters or exits passage 10.

Section 12 has its portion of passage 10 physically divided vertically into corridors 12A, 12B, 12C, and 12D, by enclosures 12E. The multi-corridor structure allows multiple UAV travel simultaneously in their dedicated corridors at the same longitude and latitude, but at different altitudes without any chance of collision. An advantage of superposing the multiple corridors vertically lies in the low construction cost associated with gaining right-of-way in the urban areas. It should be noted that certain parts of the enclosures 12E can take advantage of the existing housing 10H without redundancy.

Each corridor has at least one aperture 12G at each end, in connection with a preparation section 17 which is substantially larger than the corridor, allowing multiple UAVs to simultaneously park, recharge or replace their batteries, launch, land, and hover waiting for instructions within the preparation section 17. As shown in FIG. 1, the UAV 11F is landing and UAV 11E is taking off in the preparation section 17.

FIG. 1 shows that the UAV 11C and 11D are traveling inside the corridor 12A and 12B designated in the travel direction from the UAV terminal 11B to the UAV terminal 11A. The UAV 11G and 11H are traveling inside the corridor 12C and 12D designated in the travel direction from the UAV terminal 11A to the UAV terminal 11B.

The UAV passage 10 is supported by an elevated viaduct 13, a bridge that consists of a series of piers, to avoid interruption of busy urban ground transportation. It should be noted that the UAV passage can also be built underground as a tunnel. Other alternative UAV passage construction arrangements taking advantage of the existing infrastructure with rights of the way on the ground, or inside the restricted/controlled airspaces are also envisioned, for example, attaching the UAV passage to the existing elevated highway, motorway, power line networks, or bridges, converting the underused railway tunnel or rail transit corridor into UAV passage, building the UAV passage along with the waterways, constructing UAV three-dimensional passage networks connecting the existing high-rise buildings with hospitals or direct delivery parcel distribution centers, as well as transportation hubs such as airports, heliports, seaports, railway yards/stations, or bus stations, etc.

It should be emphasized that although the illustrated UAV passage is in general oriented horizontally, the vertical passage with multi-corridors can also be built, either outside or inside a high-rise building.

The housing 10H and enclosure 12E, as well as the viaduct 13, are made of any suitable construction material including but not limited to steel bar reinforced concrete, glass fiber reinforced concrete (FRC), fiber-reinforced plastic using glass fiber (fiberglass), other suitable polymers, plastic, suitable metals such as steel, steel alloy or aluminum alloy, architectural strengthened or laminated glass, treated or untreated wood, corrugated sheet in Fiberglass Reinforced Plastic (FRP)/metal/acrylic/polycarbonate, or composites combining the above-mentioned material, etc.

The gates 10G are configured in a way that once closed, create an airtight path space in the UAV passage. The gate 10G can be an automatic type and equipped with sensors and detectors, being capable of UAV identity recognition and performing other safety/security checks.

FIG. 1 and FIG. 1A also show that the UAV passage 10 is provided with integrated communication and indoor positioning module 14 that is composed of a plurality of communication nodes 14B, a plurality of indoor positioning units 14C, and a plurality of anemometers 14W, being deployed along with the UAV passage 10, as well as a ground computer 14D outside the path space. Each node 14B is in a wired connection with the ground computer 14D using a cable 14A, either a type of Ethernet cable or a type of fiber optic cable.

The indoor positioning unit 14C and the anemometer 14W are in wired or wireless connection with 14B.

It should be noted that the wired connection achieved by cable 14A can also be realized wirelessly with the suitable type of radio signal booster, extender, or repeater.

Each node 14B contains a ground module of telemetry radio, a radio platform that covers a section of corridor 12 of approximately 500 meters. Node 14B is capable of setting up telemetry connection, as well as command and control link with air module of telemetry radio integrated into the autopilots on board of traveling UAV at a certain frequency, for example, 915 MHz or 2.4 GHz. Upon receiving the data or instruction, the node 14B automatically store them, and then
relay wirelessly the instructions from the ground computer 14D located outside the path space to the autopilots of the UAV traveling inside the path space;
relay the flight data from the UAV to the ground computer 14D for UAV monitoring and flight control, through the high-speed wired connection using cable 14A.

There are substantial overlaps between the coverage of one node 14B and another node, so once connected in a network, they create full coverage of the path space accessible by the UAV.

In addition to the flight data received from the UAV, the measuring results from the climate weather sensors, for example, anemometer 14W for the wind speeds and the wind directions are also transferred to the ground computer 14D to verify the fitness of each location for UAV travel. The anemometers can be any suitable type including but not limited to cup type, vane type, hot-wire type, Laser-Doppler type, ultrasonic type, pressure type, or digitally instrumented type, etc.

Each unit 14C contains at least three radio signal readers or three ultrasonic signal readers with fixed known positions, being paired with a time-distance reporter integrated into the node 14B of communication module 14. When a small mobile transmitter tag (not shown in the figures) carried by the traveling UAV enters the section of the corridor covered by the unit 14C, the time-distance reporter is capable of measuring the distance between the mobile transmitter tag and each signal reader, determining accurately the position of the UAV from the three or more distances measured, and reporting in real-time the position of the UAV to the ground computer 14D through the communication module.

The UAV may carry a mobile transmitter tag all the time as a permanent permit to access the UAV passage or it may pick up a temporary one at the entrance gate 10G and drop off the tag at the exit.

It should be noted that other suitable indoor positioning technology can be applied to the UAV passage, for example, a proximity-based system, laser-based system, WIFI based system, and Infrared (IR) system. The measurement principle can be based on distance only or angle and distance.

The ground computer 14D, with ground version software about the communication network, the telemetry, the indoor positioning, the logistics management, provides an interface for human control of UAV from outside the path space, either directly at the computer 14D or indirectly by remote control in wired or wireless connection with computer 14D. The interface can take any suitable form, for example, it may resemble a virtual cockpit which includes but is not limited to multiple monitoring screens, the control joystick, and throttle. The screens show maps, views of the surveillance camera, data of UAVs in the UAV passage 10 versus the planned waypoints, as well as information about the articles to be delivered.

The ground computer 14D, with ground version software about the flight mission planning and operation, traffic control, as well as safety and security surveillance, is also capable of directing autonomous UAV flights or UAV deliveries, through the UAV passage 10, with activated waypoint flight mode on UAV. For example, the set of waypoints are set up according to the exact longitude, latitude, and altitude of the points along the centerlines of the corridor 12A, 12B, 12C, and 12D. The possible routings can be identified by considering the available openings 12P along each corridor. The possible flight plans can be determined by identifying available empty flying blocks, a slot of moving path space reserved for only one UAV, respecting the safety standard in terms of minimum separation, taking into account the UAV flights already in execution or scheduled represented by the occupied flying blocks. Therefore scheduling a new UAV travel request resembles filling the empty flying blocks available. Detailed guidance can also be given to each UAV to either follow the planned UAV block or switch to an alternative block for rerouting in case of accidents or undesirable flying conditions such as strong wind picked up by the anemometer 14W.

The ground computer 14D is also capable of pre-checking the fitness of the particular UAV before issuing a permit and loading the flight plan including the chosen set of waypoints corresponding to the coordinates of the points inside the UAV passage 10.

It should be noted that the computer 14D can be any suitable type of machine that can be instructed to carry out sequences of arithmetic or logical operations automatically via computer programming.

The UAV passage is provided with a power line 15A and an internal lighting unit 15 that is capable of meeting the minimum illumination requirement for the UAV operation, for example at a level greater than 50 lux. The lighting unit contains a plurality of lamps 15B based on light-emitting diode (LED), halogen lamps, fluorescents, or the incandescent light bulb.

The battery charging stations deployed along with the passage are also envisioned by the present invention, for example, the deployment of wired or wireless charging pads, etc.

As shown in FIG. 1 and FIG. 1A, the UAV passage 10 is also equipped with an air density regulation unit 16 comprising
a plurality of local self-regulated valves 16AA with the capacity of measuring the air density of the path space at the planned sites, each in connection with an auxiliary compressed air reservoir 16RA, In operation, the self-regulated valve 16AA lets the auxiliary reservoir 16RA feed the path space with stored the compressed air when the measured air density is below the predetermined level and exhaust the air from the path space when the measured air density is higher than the predetermined level;
a separate pipeline 16C connects the auxiliary reservoirs with the main reservoir 16RM, a main self-regulated valve 16AM, and an air compressor 16B. In operation, sensing the air pressure drop in the pipeline 16C by the self-regulated valve 16AM, the main compressed air reservoir 16RM starts to replenish the air in the auxiliary reservoir 16RA to quickly restore the target tank pressure level and meanwhile, the air compressor 16B starts to draw air from outside, pump and store them in the main reservoir 16RM until the target tank pressure level is reached.

Such a pressurized path space with air density stabilized at a predetermined level greater than 1.2 kg/m³, enables the production of a consistent UAV lift and improved its power efficiency regardless of the actual altitude the UAV is flying. It should be noted that other suitable air pressure increasing techniques may be applied instead of using mechanical compressors.

It should also be noted that instead of measuring air density directly, other techniques of indirect determination of the air density level are envisioned. For example, by measuring temperature, humidity, and air pressure, a firmware integrated into the local self-regulated valve can calculate the air density level according to the known relationships.

FIG. 1A depicts the same embodiment of the present invention as in FIG. 1 with additional details of
openings 12P in the corridor enclosure 12E and their roles of allowing the traveling UAV to switch from one corridor to another, enabling surpassing one slow-moving UAV by another fast-moving UAV;
a layer of electromagnetic interference (EMI) shielding 18 being disposed of next to the enclosure;
a layer of resilient lining 19 with corrugation being disposed of next to the enclosure.

Two examples of the traveling UAV switching from one corridor to another corridor are shown in FIG. 1A. The UAV 11F switches from position 11FB in corridor 12D to position 11FA in the corridor 12C. The UAV 11D switches from position 11DB in corridor 12A to position 11DA in corridor 12B. In general, any two UAVs in the same corridor fly one after another respecting a safe separation distance. FIG. 1A demonstrates that the presence of the openings 12P in the corridor make surpassing between UAVs possible without compromising safety. It is also envisioned by the present invention to set up a general UAV travel speed range for each corridor.

Section 12 of passage 10 is furnished with EMI shielding 18 next to the housing 10H and enclosure 12E. Although shielding 18 is presented here as a separate layer in this embodiment, it should be understood that it can well be integrated with housing 10H, enclosure 12E, or resilient lining 19. For example, a conductive coating may be applied to the surfaces of the housing, the enclosure, or the lining. The shielding can be made of any suitable material with a certain texture capable of offering shielding effectiveness greater than 30 dB, including but not limited to copper or aluminum sheet, foil or mesh, as well as conductive fabric, conductive textile, conductive foil or mesh made of nylon or polyester metalized with nickel and copper, ferrite absorber tile, pyramidal absorber foam, or conductive rubber/conductive elastomer.

FIG. 1A, FIG. 1B and FIG. 1C shows the arrangement of a resilient lining 19 that offers noise dampening in the populated urban zone and impact attenuation in case of crash accidents, protecting the UAV, the articles that the UAV carries, as well as the structure of the UAV passage. Lining 19 is made of any suitable material including but not limited to
rigid foams with polyurethane, polyethylene, polyisocyanurate, polystyrene, fiberglass, polyester fiber, or metal;
composite foams for absorption, or sandwich composite foam,
corrugated sheet in Fiberglass Reinforced Plastic (FRP), metal, acrylic, or polycarbonate.

The internal surface of lining 19 has corrugation, with grooves extended generally in directions perpendicular to the longitudinal direction of the corridor, increasing the airflow resistance and pressure drag through the UAV passage and the corridors.

As shown in FIG. 1B, the UAV 11F flies from right to left, leaving behind the propeller vortices moving from left to right. Since the UAV flies at relatively low speeds, usually laminar boundary layer flow condition develops near a smooth housing or enclosure surface. However, in the case shown in FIG. 1B, when the vortices hit the corrugated surface of lining 19, the boundary layer separation occurs and turbulences form in proximity to the corrugation behind the UAV. The occurrence of boundary layer separation and turbulences increases pressure drag and dissipates rapidly the kinetic energy of the airflow into frictional heat. It helps restore the still air environment behind the traveling UAV 11F faster than the case of smooth surface, shortening the required minimum separation distance between any two UAVs and increasing the flow capacity of the UAV passage.

FIG. 2B depicts an alternative embodiment of the present invention to the one presented in FIG. 1B. A UAV passage 20, identical to the UAV passage 10 except for the configuration of shielding 28 and the resilient lining 29 that are both shaped in a corrugation. Both the shielding 28 and the lining 29 are disposed of next to the enclosure 22E defining a generally column-shaped zone 22DL around the centerline of the corridor 22D, and a generally ring-column-shaped zone 22DT between the internal surface of the enclosure 22E and the external surface of the shielding 28.

Each corrugation groove has two flanks, each flank defining a surface normal vector 29NA or 29NB. The positive normal vector 29NA pointing to the zone 22DL takes an acute angle 29A with the designated travel direction of the corridor, while the other positive normal vector 29NB pointing to the zone 22DL takes an obtuse angle 29B with the designated travel direction of the corridor. Instead of making general perforation evenly across the corrugated surface, a plurality of perforation is made only on the flank of the groove with the normal vector 29NA, making lining 29 and shielding 28 permeable to achieve a preferential flow resistance.

In operation, as shown in FIG. 2B, the UAV 21F flies from right to left, leaving behind the propeller vortices moving from left to right. When the vortices hit the corrugation, boundary layer separation occurs and turbulences form in proximity to the corrugation behind the UAV. Meanwhile, a portion of the air passes through perforated holes 29P created only on the group of the flanks with surface vector 29NA, from zone 22DL to zone 22DT. As shown in FIG. 2, a new relatively strong airflow passes through the holes 29P at the point 22DT1 where the propeller vortices just hit. The increase of air pressure in zone 22DT1 helps develop reverse airflows in the zone 22DT2 and 22DT3 against the incoming airflows through the nearby perforated holes, resulting in a preferential resistance, an additional pressure drag, to airflow from left to right. It is acknowledgeable that the above configuration will not develop reverse airflow if the UAV 21F flies from left to right.

It should be noted that the same increase of air pressure in zone 22DT1 results in airflow from zone 22DT4 to part of the zone 22DL ahead of the UAV that remains still-aired. This airflow helps propel and float the moving UAV 21F.

It should be noted that it is the intent of the present invention to diminish the airflows left behind a traveling UAV by quickly converting the kinetic energy of the airflow to frictional heat and to restore the still-air environment as quickly as possible for the next UAV passing the same section of the path space. To achieve this purpose,
the corrugation is shaped either on the internal surface of the enclosure or the housing when no lining is present or the corrugation is shaped on the internal surface of the lining when it is furnished or in other words, corrugation being formed on the immediate boundary of the path space accessible by the UAV;
the mesh-like perforation 29P is structured, making the lining permeable;
the reversing airflow in zone 22DT is created, resulting in additional turbulences in the preferential direction.

All the above help dissipate the kinetic energy quickly into frictional heat in the air.

Other alternative arrangements using one-way active check valves or passive check valves, for example, Tesla valvular conduit are envisioned to achieve a preferential airflow resistance.

It should be noted that lining 19 can act as thermal insulation being disposed of next to the enclosure and the housing. With further temperature sensors, heating and/or cooling equipment in place, the UAV passage may acquire the capacity of temperature regulation.

The present invention has been described in connection with the preferred embodiments of the various figures. It is to be understood that other similar embodiments may be used, or modifications and additions may be made to the described embodiment for performing the same function of the present invention without deviating therefrom. Therefore, the present invention should not be limited to any single embodiment, but rather construed in breadth and scope in accordance with the recitation of the appended claims.

The invention claimed is:

1. An apparatus for aerial transportation using an unmanned aerial vehicle (UAV), the apparatus comprising:
(1) the first UAV terminal and the second UAV terminal;
(2) at least one UAV passage with housing connecting the first UAV terminal and the second UAV terminal, the housing confining a path space where UAV travels within, and the housing being configured to reduce substantially the airflows through the housing;
(3) at least two apertures in the housing, at least one aperture at the first UAV terminal and the other at the second UAV terminal, each aperture being equipped with a gate; the gate being generally kept closed and being opened when a UAV enters or exits the UAV passage, the gate being configured to reduce substantially the airflows through the gate;
(4) a communication module carrying command and control data of the UAV traveling in the path space and telemetry data about the flight status of the UAV traveling in the path space to a ground computer located outside the path space.

2. The apparatus of claim 1, wherein the UAV passage has at least one multi-corridor section where the UAV passage is divided into a plurality of corridors that are spaced apart. Each corridor has its enclosure configured to reduce substantially airflows through the enclosure of the corridor. Each corridor has a plurality of openings allowing the UAV to enter, exit, or switch between the corridors. The multi-corridor section has at least one corridor designated for UAV travel in one direction and the rest designated for UAV travel in the opposite direction.

3. The apparatus of claim 2, wherein the multi-corridor section has its corridors superposed vertically when the UAV passage, in general, extends horizontally, therefore allowing multiple UAVs traveling simultaneously at the same longitude and the same latitude while each UAV is traveling in a corridor at a different altitude.

4. The apparatus of claim 1, wherein the communication module has a plurality of nodes being deployed along with the UAV passage. Each node contains at least one transceiver telemetry radio being capable of communicating wirelessly with the UAV in a section of the path space. The nodes are in wired connection with the ground computer, enabling telemetry in networking, as well as UAV command and control in networking.

5. The apparatus of claim 1, further comprises at least one network-based indoor positioning module enabling tracking the positions of the UAVs in the path space with a positioning accuracy of plus-minus 10 centimeters or less.

6. The apparatus of claim 5, wherein the indoor positioning module comprises at least a mobile transmitter tag carried by a UAV in the path space, a plurality of radio signal based or ultrasound signal based stationary positioning units being deployed along with the UAV passage. Each unit covers a section of the UAV passage and contains at least three signal readers with fixed known positions, and a time-distance reporter integrated with the communication module being capable of measuring the distances between the tag and the signal readers and reporting the position of the UAV to the ground computer.

7. The apparatus of claim 1, further comprising a lighting unit configured to provide illumination of the path space with a light intensity greater than 50 Lux, enabling positioning, monitoring, and control of the UAVs in the path space.

8. The apparatus of claim 1, wherein the UAV passage has at least two preparation sections substantially wider and taller than the rest, allowing multiple UAVs in the preparation section to simultaneously launch, land, hover or travel through the preparation section. There is at least one preparation section located in proximity to the first UAV terminal, and at least one preparation section located in proximity to the second UAV terminal.

9. The apparatus of claim 1, further comprises an air density regulating unit being capable of determining the air density of the path space and regulate the air density at a predetermined level equal to or greater than 1.2 kg/m³. The air density regulating unit increases the air pressure of the path space when the air density is below the predetermined level and reduces the air pressure of the path space when the air density is above the predetermined level. The housing and the gate are configured to create a closed path space when the gates are closed.

10. The apparatus of claim 9, wherein the air density regulating unit contains
a plurality of self-regulated valves, each paired with an auxiliary compressed air reservoir, each being coupled to the path space and capable of adjusting the level of the air density of the path space by either automatically releasing the compressed air to the path space from the auxiliary compressed air reservoir, or exhausting the air from the path space;
at least a self-regulated valve, paired with one main compressed air reservoir and an air compressor, being connected with the auxiliary compressed air reservoirs and being capable of automatically replenishing the auxiliary compressed air reservoirs.

11. The apparatus of claim 1, further comprises an electromagnetic interference shielding covering at least a section of the UAV passage to reduce at least partially the coupling of radio waves, electromagnetic fields, or electrostatic fields between the interior and exterior of the UAV passage.

12. The apparatus of claim 2, wherein the immediate boundary of the path space where the boundary layer airflow condition develops, has corrugation with grooves extended generally in directions perpendicular to the longitudinal direction of the corridor, increasing the airflow resistance through the corridor.

13. The apparatus of claim 2, further comprises a resilient lining in proximity to the housing and/or to the enclosure, enabling dampening of the noise generated by the UAV traveling in the path space and impact attenuation in case of an accident.

14. The apparatus of claim 2, further comprises a permeable lining in proximity to the housing and/or to the enclosure, increasing the airflow resistance through the corridor.

15. The apparatus of claim 2, wherein the corridor is configured to increase the airflow resistance through the corridor preferentially in the direction opposite to the designated direction for UAV travel.

16. The apparatus of claim 1, further comprises a plurality of anemometers being deployed along with the UAV passage and being connected to the communication module for monitoring the wind speeds and wind directions in the path space.

17. The apparatus of claim 1, wherein the UAV passage has at least an elevated section where the bottom of the housing is substantially higher than the ground level, avoiding interruption of ground transportation.

18. The apparatus of claim 1, wherein the UAV passage has at least one underground section where the top of the housing is substantially lower than the ground level, avoiding interruption of ground transportation.

19. The apparatus of claim 1, further comprises at least one UAV battery charging station or one UAV battery replacement station installed along with the UAV passage.

20. The apparatus of claim 1, wherein the ground computer, with the aid of the communication module, is capable of
(1) storing a plurality of pre-programmed flight routes that include sets of waypoints inside the UAV passage, and loading the chosen flight routes to the UAVs;
(2) monitoring and indicating the flight status of the UAVs traveling in the path space, as well as the reliability status of the apparatus;
(3) performing scheduling and traffic control of UAV flights autonomously according to the safety standard, the UAV flights in execution, and the UAV flights scheduled;
(4) performing security and safety clearance checks on the UAV before it enters the path space;
(5) instructing the UAV during the flight operation through the command and control of the communication module and guiding the UAV to switch to an alternative flight route when the condition changes in the UAV passage.
